(19) United States
(12) Patent Application Publication
(10) Pub. No.: US 2024/0321795 A1
(43) Pub. Date: Sep. 26, 2024

(54) METHOD FOR MANUFACTURING A PLURALITY OF ELECTRONIC COMPONENTS

(71) Applicant: STMicroelectronics International N.V., Geneva (CH)

(72) Inventors: Olivier ORY, Tours (FR); Michael DE CRUZ, Monnaie (FR)

(73) Assignee: STMicroelectronics International N.V., Geneva (CH)

(21) Appl. No.: 18/603,113

(22) Filed: Mar. 12, 2024

(30) Foreign Application Priority Data
Mar. 22, 2023 (FR) 2302713

(51) Int. Cl. H01L 23/00; H01L 21/288; H01L 21/463; H01L 21/768; H05K 1/18

(52) U.S. Cl. CPC H01L 24/13; H01L 21/288; H01L 21/463; H01L 21/76865; H01L 24/29; H01L 24/73; H05K 1/181; H01L 2224/13007; H01L 2224/13025; H01L 2224/29005; H01L 2224/2919; H01L 2224/73153; H01L 2924/01029

(57) ABSTRACT

The present disclosure relates to a method of manufacturing first electronic components, each comprising a second electronic component, each second component comprising at least two contact metallizations, the method comprising: a) forming, on a substrate, at least two metal pillars; b) forming, over a portion of the surface of each pillar, a metallization of the component; c) covering the surface of the substrate, the pillars, and the metallizations of the first components with a first resin layer; d) removing the substrate to expose a surface of the pillars, opposite to the metallizations of the components; e) bonding and electrically connecting the second components, by their metallizations, to the surface of the pillars opposite to the metallizations of the first components; and f) expose the surface of the metallizations of the first components opposite to the pillars.

### CROSS-REFERENCE TO RELATED APPLICATION(S)

This application claims the priority benefit of French patent application number 2302713, filed on Mar. 22, 2023, entitled “Procédé de fabrication d'une pluralité de composants électroniques” which is hereby incorporated by reference to the maximum extent allowable by law.

### BACKGROUND

### Technical Field

The present disclosure concerns a method of manufacturing electronic components, each comprising an electronic chip. It more particularly aims at a method of manufacturing electronic components called surface mounted devices (SMD), that is, comprising, on the side of at least one surface, at least two contact metallizations intended to be soldered to corresponding connection areas of an external device, for example, a printed circuit board or another electronic component.

### Description of the Related Art

Many surface-mounted electronic component manufacturing methods have been provided. An embodiment overcomes all or part of the disadvantages of known surface-mounted electronic component manufacturing methods.

### BRIEF SUMMARY

One embodiment provides a method of manufacturing a plurality of first electronic components, each comprising a second electronic component, each second electronic component comprising at least two contact metallizations on the side of a connection surface of the second electronic component, the method comprising the following successive steps:
a) forming, on a surface of a substrate, for each second electronic component, at least two metal pillars intended to be respectively connected to said at least two contact metallizations of the second electronic component, said metal pillars each having a surface area greater than the surface area of the corresponding contact metallization of the second electronic component;
b) forming, over a portion only of the surface of each metal pillar, a contact metallization of the electronic component;
c) covering said surface of the substrate, the metal pillars, and the contact metallizations of the first electronic components with a first resin layer;
d) removing the substrate to expose a surface of the metal pillars, opposite to the contact metallizations of the electronic components;
e) bonding and electrically connecting the second electronic components, by their contact metallizations, to the surface of the metal pillars opposite to the contact metallizations of the first electronic components;
f) thinning the first resin layer to expose the surface of the contact metallizations of the first electronic components opposite to the metal pillars; and
g) cutting the first resin layer to individualize the first electronic components.

According to an embodiment, the metal pillars are formed by electrolytic growth.

According to an embodiment, the contact metallizations of the first electronic components are formed by electrolytic growth.

According to an embodiment, the method comprises, after e) a step of covering of the second electronic components and of the contact metallizations of the first electronic components with a second resin layer.

According to an embodiment, during the cutting of step g), the sides of the metal pillars and of the contact metallizations of the first electronic components are exposed.

According to an embodiment, the metal pillars are made of copper, of gold, of tin, of silver, or of an alloy of a plurality of these materials.

According to an embodiment, the contact metallizations of the first electronic components are made of copper, of gold, of tin, of silver, or of an alloy of a plurality of these materials.

According to an embodiment, the contact metallizations of the first electronic components have a height in the range from 20 μm to 100 μm.

According to an embodiment, the contact metallizations of the first electronic components have a height greater than or equal to 30 μm.

According to an embodiment, the metal pillars have a height in the range from 80 μm to 150 μm.

According to an embodiment, during step g), the cutting of the first resin layer is performed so that the first resin layer remains on sides of the electronic component.

According to an embodiment, during step g), the cutting of the first resin layer is performed so that, at the end of this step, the contact metallizations of the first electronic components and the metal pillars are flush with the sides of the electronic component.

According to an embodiment, during step g), a first through cutting line is formed so that the contact metallizations of the first electronic components and the metal pillars are flush with the sides of the electronic component and a second non-through cutting line, having a cutting width greater than the cutting width of the first cutting line, is formed to expose a portion of the surface of the metal pillars opposite to the contact metallizations of the first electronic components.

According to an embodiment, after step e), the structure is stored for later use.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1 is a perspective view illustrating two surface-mounted electronic components; and

FIG. 2A, FIG. 2B, FIG. 2C, FIG. 2D, FIG. 2E, FIG. 2F, FIG. 2G, FIG. 2H, FIG. 2I, FIG. 2J, FIG. 2K, FIG. 2L, FIG. 2M, and FIG. 2N are partial simplified cross-section and top views of successive steps of a method of manufacturing a surface-mounted electronic component according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the forming of semiconductor chips of the described electronic components has not been detailed, the described embodiments being compatible with all or most known semiconductor chips or the forming of such chips being within the abilities of those skilled in the art based on the indications of the present disclosure.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made, unless specified otherwise, to the orientation of the figures.

Unless specified otherwise, the expressions “around”, “approximately”, “substantially” and “in the order of” signify within 10%, and preferably within 5%.

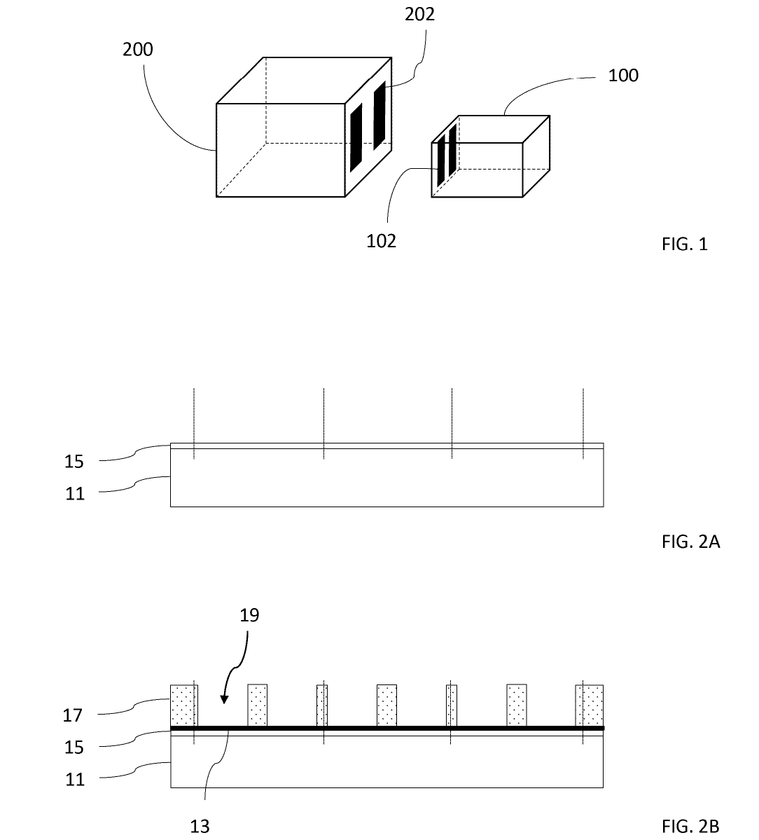

FIG. 1 is a perspective view illustrating two surface-mounted electronic components 100 and 200, intended to be assembled in more complex electronic systems.

Components 100 and 200 are for example components of CSP (“Chip Scale Package”) type, each comprising a semiconductor chip (not detailed in the drawing) and, on the side of at least one surface of the component, called connection surface, at least two contact metallizations 102, respectively 202, connected to connection terminals (not visible in the drawing) of the semiconductor chip. In the example of FIG. 1, component 100 comprises two contact metallizations 102 and component 200 comprises two contact metallizations 202. Each of components 100 and 200 for example has lateral dimensions (parallel to the connection surface) substantially equal to the lateral dimensions of the chip that it contains. In each of components 100 and 200, the semiconductor chip of the component is essentially formed by a portion of a semiconductor substrate (not detailed in the drawing), for example, made of silicon, inside and on top of which are integrated semiconductor components (not detailed in the drawing). As an example, the back side of component 100, respectively 200, that is, its surface opposite to the connection surface, is formed by the back side of the semiconductor substrate of the chip that it contains, that is, the surface of the substrate opposite to the semiconductor components. As an example, the sides of component 100, respectively 200, are at least partly formed by the sides of the semiconductor substrate of the chip that it contains. As an example, a protective resin laterally surrounds contact metallizations 102, respectively 202, on the side of the connection surface of the component.

Electronic components 100 and 200 are for example similar except for their dimensions, component 100 being smaller than component 200. The lateral dimensions of the connection surface of component 200 are for example greater than 0.85 mm by 0.5 mm, for example in the order of 1 mm by 0.6 mm. The lateral dimensions of the connection surface of component 100 are, for example, smaller than 0.75 mm by 0.4 mm, for example in the order of 0.6 mm by 0.3 mm.

As an example, components 100 and 200 perform the same function, for example a function of protection against electrostatic discharges.

For the assembly of components 100, respectively 200, contact metallizations 102, respectively 202 of the component are transferred onto corresponding contact metallizations of an external device, for example a printed circuit board or another electronic component.

Due to its reduced dimensions, component 100 has the advantage of being less expensive than component 200, particularly due to the fact that the semiconductor chip that it contains is smaller than the semiconductor chip of component 200. Thus, component 100 uses for its manufacturing a semiconductor substrate portion of smaller surface area than component 200.

In other words, the progress in terms of miniaturization enables to decrease the cost of electronic components by decreasing the semiconductor substrate surface area used for their manufacturing.

However, this miniaturization may raise assembly issues in certain situations. For example, in an electronic system sized to accommodate component 200, substituting component 100 to component 200 risks resulting in a short-circuit or to an open circuit of the contact metallizations 102 of component 100 during the assembly or may lead to an open circuit, as the contact metallizations 102 of the component 100 are not in contact with the corresponding contact metallizations of an external device, such as a printed circuit board or other electronic component.

A possibility to avoid this problem would be to resize the metallizations of the electronic system intended to receive the component. However, this implies developments at the scale of the system likely to generate a significant excess cost.

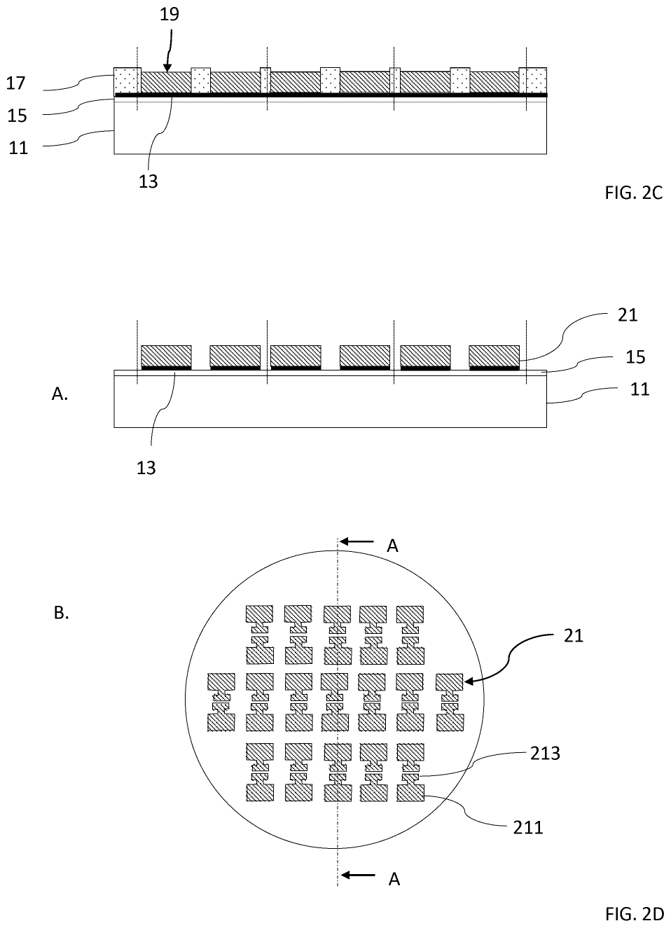

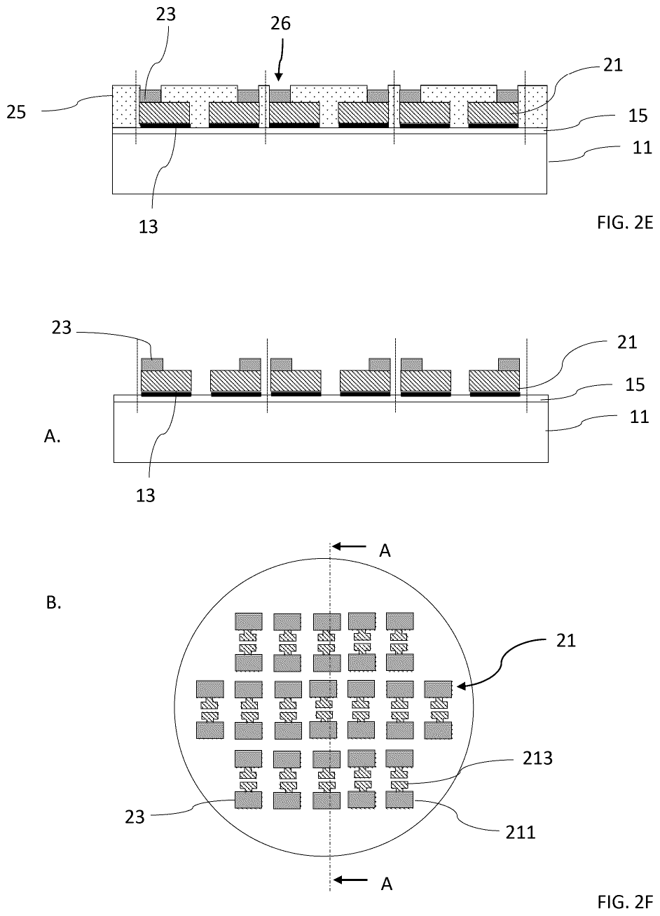

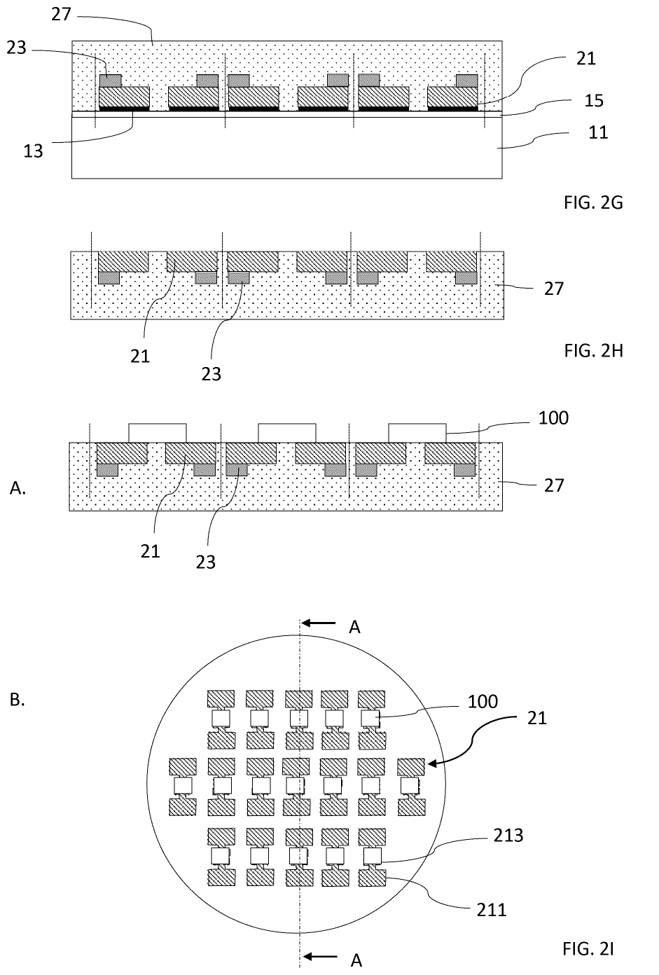

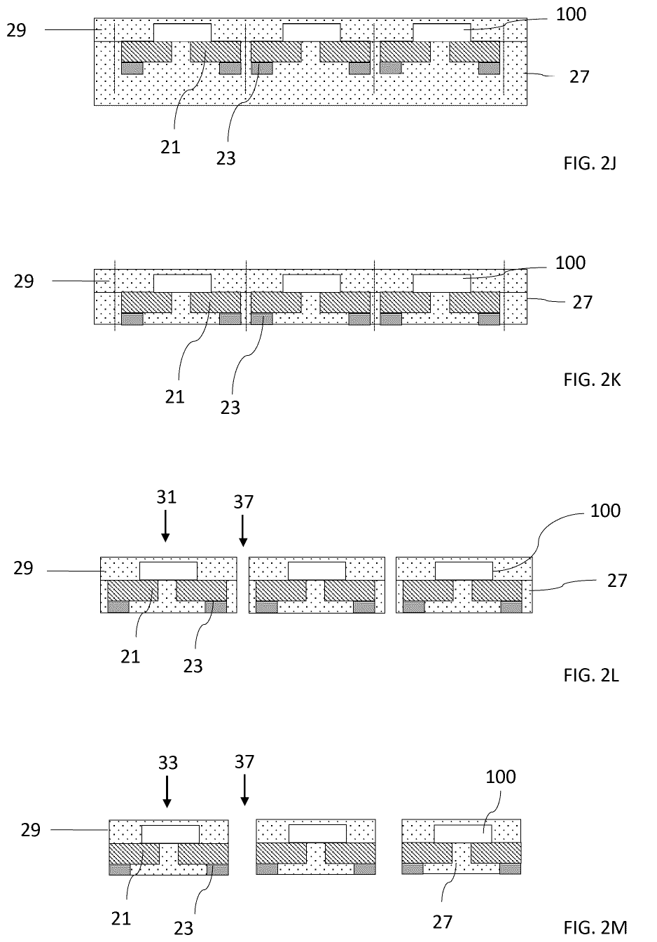

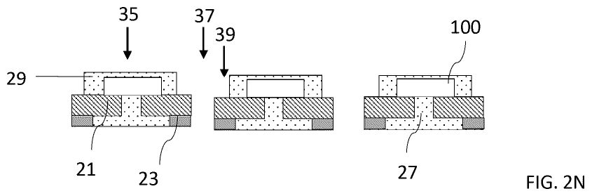

FIG. 2A, FIG. 2B, FIG. 2C, FIG. 2D, FIG. 2E, FIG. 2F, FIG. 2G, FIG. 2H, FIG. 2I, FIG. 2J, FIG. 2K, FIG. 2L, FIG. 2M, and FIG. 2N are partial simplified cross-section and top views of successive steps of a method of manufacturing a surface-mounted electronic component according to an embodiment.

FIG. 2A illustrates an initial structure comprising a substrate 11. Substrate 11 for example corresponds to a wafer of a semiconductor material, for example, silicon. As a variant, substrate 11 corresponds to a wafer of a non-semiconductor material, for example, glass.

Substrate 11 has, for example, a thickness in the range from 150 μm to 900 μm, preferably in the range from 250 μm to 650 μm, for example, in the order of 500 μm.

In the shown example, the initial structure comprises a passivation layer 15, for example, made of silicon oxide, coating the entire upper surface of substrate 11. Passivation layer 15 is for example in contact, by its lower surface, with the upper surface of substrate 11. As a variant, passivation layer 15 may be omitted.

It should be noted that a plurality of electronic components are manufactured from a same initial structure such as illustrated in FIG. 2A. In the structures illustrated hereafter, three electronic components are formed, delimited by dotted lines. In practice, the number of electronic components formed from the initial structure may be much greater.

FIGS. 2B to 2D illustrate steps of forming of metal pillars 21 on the upper surface side of substrate 11, for example, on the upper surface of passivation layer 15.

More particularly, for each electronic component, one metal pillar 21 per contact metallization 102 of the component 100, that is, two metal pillars 21 per component in the shown example, is formed.

Metal pillars 21 are for example formed by local electrolytic growth. For this purpose, a priming or bonding layer 13 is first continuously deposited with a substantially uniform thickness over the entire upper surface of substrate 11, for example, on top of and in contact with the upper surface of passivation layer 15. Layer 13 is for example made of a metallic material, for example, of copper. As a variant, layer 13 is a stack of a plurality of conductive layers, for example, of UBM (“Under Bump Metallization”) type. Bonding layer 13 has, for example, a thickness smaller than 5 μm, for example smaller than 3 μm.

As a variant, bonding layer 13 may be located at the surface of substrate 11 at the step of FIG. 2B.

FIG. 2B illustrates a structure obtained at the end of a step of forming of a first resin layer 17 on the upper surface of bonding layer 13.

As an example, during this step, resin layer 17 is formed over the entire wafer, that is, it is formed so that it covers the entire surface of the upper surface of the structure illustrated in FIG. 2A. The deposition of resin layer 17 is for example performed by centrifugation.

Resin layer 17 is for example made of a resist.

At the end of the step of deposition of resin layer 17, the latter is submitted, for example, to a photolithography so that it is locally removed by forming openings 19.

As an example, during this step, an opening 19 is formed for each future pillar 21.

FIG. 2C illustrates a structure obtained at the end of a step of forming of metal pillars 21.

More particularly, during this step, metal pillars 21 are formed in openings 19. As an example, metal pillars 21 are formed by electrolytic growth.

Metal pillars 21 are for example made of copper, of gold, of tin, of silver, or of an alloy of a plurality of these materials. As an example, the composition of metal pillars 21 is homogeneous, that is, it is the same along the entire height of each metal pillar 21. As an example, metal pillars 21 are not formed of a superposition of a plurality of different materials. As an example, pillars 21 have a height, at the end of this step, in the range from 50 μm to 250 μm, for example in the range from 80 μm to 150 μm, for example in the order of 100 μm.

FIG. 2D illustrates, in a cross-section view A and a top view B, a structure obtained at the end of a step of removal of resin layer 17, view A being a cross-section view along the cross-section plane AA of view B.

More particularly, during this step, resin layer 17 is removed to expose the upper surface of substrate 11 and, if present, the upper surface of bonding layer 13 and/or passivation layer 15. As an example, during this step, the removal of resin layer 17 is accompanied by the removal of the portions of bonding layer 13 not covered with pillars 21.

As a variant, pillars 21 may be locally formed by silk-screening with no prior deposition of resin layer 17.

As an example, metal pillars 21 comprise a first portion 211 and a second portion 213. The first portion 211 of each metal pillar 21 is for example intended to be coupled to an external device, for example, adapted to receiving components of the type of component 200. The second portion 213 of each metal pillar 21 is for example intended to be connected to a component, for example, of the type of component 100. As an example, the portions 213 of metal pillars 21 are similar by their shape and their dimensions to the contact metallizations 102 of components 100. As an example, metal pillars 21 are gathered at least two by two so that, in a subsequent step, a same component is connected by their second portions 213 to at least two metal pillars 21. As an example, pillars 21 are gathered so that the number of pillars 21 connected to a same component is identical to the number of contact metallizations of this component, a pillar 21 being connected to a contact metallization.

FIGS. 2E and 2F illustrate steps of forming of contact metallizations 23 on the upper side surface of the structure illustrated in FIG. 2D.

More particularly, there is formed, in this example, in front of each pillar 21, a contact metallization 23.

FIG. 2E illustrates a structure obtained at the end of a step of forming of a contact metallization 23 for example by electrolytic growth.

More particularly, during this step, and similarly to what has been described in relation with FIGS. 2B and 2C, a resin layer 25 is first deposited on the upper surface of the structure illustrated in FIG. 2D. After its deposition, resin layer 25 is for example submitted to a photolithography to form openings 26 in resin layer 25. Openings 26 are for example formed in front of metal pillars 21 and, more particularly, in front of a portion only of metal pillars 21.

Still similarly to what has been described in relation with FIGS. 2B and 2C, during this step, contact metallizations 23 there are, in a second phase, formed in openings 26. As an example, contact metallizations 23 are formed in contact with metal pillars 21. As an example, contact metallizations 23 are formed by electrolytic growth.

Contact metallizations 23 are for example made of copper, of gold, of tin, of silver, or of an alloy of a plurality of these materials. As an example, the composition of contact metallizations 23 is homogeneous, that is, it is the same along the entire height of each contact metallization 23. As an example, contact metallizations 23 are not formed of a superposition of a plurality of different materials. As an example, contact metallizations 23 have a height, at the end of this step, in the range from 20 μm to 150 μm, for example in the range from 20 μm to 100 μm. As an example, contact metallizations 23 have a height, at the end of this step, greater than or equal to 30 μm.

FIG. 2F illustrates, in a cross-section view A and a top view B, a structure obtained at the end of a step of removal of resin layer 25, view A being a cross-section view along the cross-section plane AA of view B.

More particularly, during this step, resin layer 25 is removed to expose the upper surface of pillars 21, the upper surface of substrate 11 and, if present, the upper surface of passivation layer 15.

As an example, as shown in view B of FIG. 2F, contact metallizations 23 are formed in front of the first portion 211 of metal pillars 21.

As an example, contact metallizations 23 are for example intended to be connected to a printed circuit or another electronic component adapted to receiving components of the type of component 200. As an example, contact metallizations 23 are similar by their shape and their dimensions to the contact metallizations 202 of components 200. Contact metallizations 23 and pillars 21, by their portions 213, thus enable to adapt components of the type of component 100 to a use in circuits adapted to components of the type of component 200.

As a variant, contact metallizations 23 may be locally formed by silk-screening with no prior deposition of resin layer 25.

FIG. 2G illustrates a structure obtained at the end of a step of forming of a resin layer 27 on the upper surface of the structure illustrated in FIG. 2F.

More particularly, during this step, resin layer 27 is for example deposited over the entire upper surface of the structure illustrated in FIG. 2F so that it entirely covers substrate 11, pillars 21, and contact metallizations 23.

Resin layer 27 is for example deposited by screen printing or molding.

Resin layer 27 has, for example, a thickness enabling to rigidify the structure for the subsequent steps. As an example, resin layer 27 has a thickness, taken from the upper surface of substrate 11, in the range from 100 μm to 700 μm, for example in the range from 300 μm to 600 μm.

At the end of this step, the structure may for example be stored for its subsequent use. It is here spoken of an interposer structure or mechanical adaptation structure. This storage capability allows flexibility in the production of electronic components, for example electrostatic discharge protection components.

FIG. 2H illustrates a structure obtained at the end of a step of removal of substrate 11 from the structure illustrated in FIG. 2G.

It should be noted that, in the example of FIGS. 2H to 2N, the orientation of the structures is inverted with respect to the cross-section views of the previous drawings, the upper surface of the structure illustrated in FIG. 2G then corresponds to the lower surface of the structure illustrated in FIG. 2H.

During this step, the structure illustrated in FIG. 2G is for example thinned or polished from its lower surface (that is, the upper surface of the structure illustrated in FIG. 2H), to remove substrate 11 and expose pillars 21. As an example, passivation layer 15, and for example bonding layer 13, are removed with substrate 11 during this step.

As an example, the thinning or polishing step is performed by chemical-mechanical polishing (CMP).

At the end of this step, the upper surface of the structure corresponds to a surface of resin 27 having metal pillars 21 flush therewith.

FIG. 2I illustrates, in a cross-section view A and a top view B, a structure obtained at the end of a step of bonding and electric connection of components 100 on the upper surface of the structure illustrated in FIG. 2H, view A being a cross-section view along the cross-section plane AA of view B.

During this step, components 100 are bonded to the surface of the upper side of the structure illustrated in FIG. 2H so that, for example, two neighboring metal pillars 21 are coupled by a single component 100. As an example, components 100 are connected to pillars 21 by their second portions 213. As an example, components 100 are bonded to pillars 21 by means of a solder paste. As an example, after the transfer of components 100, the structure undergoes an anneal.

Components 100 are for example individually transferred, for example, by a pick-and-place technique.

FIG. 2J illustrates a structure obtained at the end of a step of deposition of a resin layer 29 on the upper surface of the structure illustrated in FIG. 2I.

More particularly, during this step, resin layer 29 is for example deposited over the entire upper surface of the structure illustrated in FIG. 2I so that it entirely covers components 100 and the upper surface of pillars 21.

At the end of this step, components 100, linked to pillars 21 and to contact metallizations 23, are as encapsulated or molded in resin layers 27 and 29.

As an example, resin layer 27 and resin layer 29 are made of the same material. As a variant, resin layers 27 and 29 are made of different materials.

Resin layer 29 is, for example, formed with a thickness, taken from the upper surface of the composant 100, in the range from 10 μm to 100 μm, for example in the range from 10 μm to 50 μm, for example in the range from 15 μm to 25 μm. As an example, the thickness of resin layer 29 is a function of the desired size of the final electronic component.

FIG. 2K illustrates a structure obtained at the end of a step of thinning of the structure illustrated in FIG. 2J.

During this step, the structure illustrated in FIG. 2J is for example thinned or polished from its lower surface, to remove a lower portion of resin layer 27 and expose contact metallizations 23.

As an example, during this step, the thinning of the structure is stopped when the lower surface of contact metallizations 23 is exposed.

As an example, the thinning or polishing step is carried out by chemical mechanical polishing (CMP).

FIGS. 2L to 2N illustrate structures obtained at the end of different steps of cutting of the structure illustrated in FIG. 2K to form a plurality of surface-mounted components 31, 33, or 35, each component 31, 33, or 35 comprising a component 100.

More particularly, FIG. 2L illustrates a structure obtained at the end of a step of cutting of the structure illustrated in FIG. 2K, according to a first embodiment, to form a plurality of surface-mounted electronic components 31.

Prior to this step, the structure is for example transferred, by its back side, onto a support film, not shown in FIG. 2L.

During this step, through openings 37 in resin layers 29 and 27 are formed in the structure. As an example, an opening 37 is formed between each assembly of a component 100, of at least two pillars 21, and of at least two contact metallizations 23.

Openings 37 may for example be formed by sawing. Openings 37 may as a variant be formed by laser ablation.

In FIG. 2L, openings 37 are formed so that they do not expose the sides of the adjacent pillars 21. The surface-mounted electronic components thus have their sides entirely covered with resin layers 27 and 29 except for the lower side having contact metallizations 23 flush therewith.

At the end of this step, the obtained structure corresponds to a plurality of surface-mounted electronic components 31, only coupled by the support film (not shown in FIG. 2L). Surface-mounted electronic components 31 may then be sampled from this support film, for their assembly in an external device.

Similarly, FIG. 2M illustrates a structure obtained at the end of a step of cutting of the structure illustrated in FIG. 2K, according to a second embodiment, to form a plurality of surface-mounted electronic components 33.

This cutting step is for example similar to the cutting step illustrated in FIG. 2L, with the difference that the width of the formed opening 37 is greater than that described in relation with FIG. 2L.

As an example, during this step, opening 37 is formed so that it exposes the sides of pillars 21 and of contact metallizations 23. Opening 37 thus has a width greater than or equal to the distance between two pillars 21 made of two neighboring components 33.

Surface-mounted components 33 have, at the end of this step, their sides entirely covered with resin layers 27 and 29 except for their lower surface having contact metallizations 23 flush therewith and of two of the lateral sides having contact metallizations 23 and pillars 21 flush therewith. Surface-mounted components 33 then have a structure with two of their sides which are wettable.

Similarly still, FIG. 2N illustrates a structure obtained at a step of cutting of the structure illustrated in FIG. 2K, according to a third embodiment, to form a plurality of surface-mounted electronic components 35.

This cutting step is for example similar to the cutting step illustrated in FIG. 2M, with the difference that it comprises an additional partial cutting step.

As an example, during this step, in addition to opening 37, there is formed another non-through opening 39 in front of each opening 37. Openings 39 are for example formed from the upper surface of the structure illustrated in FIG. 2K. Openings 39 for example emerge onto the upper surface of pillars 21.

As an example, openings 39 have a width greater than the width of openings 37. Openings 39 may be formed by sawing. Openings 39 may as a variant be formed by laser ablation.

Surface-mounted components 35 have, at the end of this step, their sides entirely covered with resin layers 27 and 29 except for their lower surface having contact metallizations 23 flush therewith and of two of the lateral sides exhibiting a step having contact metallizations 23 and pillars 21. Surface-mounted components 35 then have a structure, three sides of which are wettable.

An advantage of the present embodiment is that it enables to offset the contact metallizations of the components to adapt a component of the type of component 100 for a use in a circuit intended for components of the type of component 200.

Another advantage of the present embodiment is that it enables to manufacture electric components at the desired final dimensions by adapting the thickness of resin layer 29, of metal pillars 21, and of contact metallizations 23.

Still another advantage is that it enables to manufacture components at lower cost.

Still another advantage is that it allows the interposer shown in FIG. 2H to be stored for later use by a component requiring footprint matching on the PCB defined by the interposer.

Various embodiments and variants have been described. Those skilled in the art will understand that certain features of these various embodiments and variants may be combined, and other variants will occur to those skilled in the art. In particular, the described embodiments are for example not limited to the examples of dimensions and of materials mentioned hereabove.

Finally, the practical implementation of the described embodiments and variations is within the abilities of those skilled in the art based on the functional indications given hereabove.

A method of manufacturing a plurality of first electronic components (31; 33; 35), each including a second electronic component (100), each second electronic component (100) including at least two contact metallizations (102) on the side of a connection surface of the second electronic component (100), the method may be summarized as including the following successive steps: a) forming, on a surface of a substrate (11), for each second electronic component (100), at least two metal pillars (21) intended to be respectively connected to said at least two contact metallizations (102) of the second electronic component (100), said metal pillars (21) each having a surface area greater than the surface area of the corresponding contact metallization (102) of the second electronic component (100); b) forming, over a portion only of the surface of each metal pillar (21), a contact metallization (23) of the electronic component (31; 33; 35); c) covering said surface of the substrate (11), the metal pillars (21), and the contact metallizations (23) of the first electronic components (31; 33; 35) with a first resin layer (27); d) removing the substrate (11) to expose a surface of the metal pillars (21), opposite to the contact metallizations (23) of the electronic components (31; 33; 35); e) bonding and electrically connecting the second electronic components (100), by their contact metallizations (102), to the surface of the metal pillars (21) opposite to the contact metallizations (23) of the first electronic components (31; 33; 35); f) thinning the first resin layer (27) to expose the surface of the contact metallizations (23) of the first electronic components (31; 33; 35) opposite to the metal pillars (21); and g) cutting the first resin layer (27) to individualize the first electronic components (31; 33; 35).

The metal pillars (21) may be formed by electrolytic growth.

The contact metallizations (23) of the first electronic components (31; 33; 35) may be formed by electrolytic growth.

The method may include after step e) a step of covering of the second electronic components (100) and of the contact metallizations (23) of the first electronic components (31; 33; 35) with a second resin layer (29).

During the cutting of step g), the sides of the metal pillars (21) and of the contact metallizations (23) of the first electronic components (31; 33; 35) may be exposed.

The metal pillars (21) may be made of copper, of gold, of tin, of silver, or of an alloy of a plurality of these materials.

The contact metallizations (23) of the first electronic components (31; 33; 35) may be made of copper, of gold, of tin, of silver, or of an alloy of a plurality of these materials.

The contact metallizations (23) of the first electronic components (31; 33; 35) may have a height in the range from 20 μm to 100 μm.

The contact metallizations (23) of the first electronic components (31; 33; 35) may have a height greater than or equal to 30 μm.

The metal pillars (21) may have a height in the range from 80 μm to 150 μm.

During step g), the cutting of the first resin layer (27) may be performed so that the first resin layer (27) remains on sides of the electronic component (31; 33; 35).

During step g), the cutting of the first resin layer (27) may be performed so that, at the end of this step, the contact metallizations (23) of the first electronic components (31; 33; 35) and the metal pillars (21) are flush with the sides of the electronic component (31; 33; 35).

During step g), a first through cutting line may be formed so that the contact metallizations (23) of the first electronic components (31; 33; 35) and the metal pillars (21) are flush with the sides of the electronic component (31; 33; 35) and a second non-through cutting line, having a cutting width greater than the cutting width of the first cutting line, may be formed to expose a portion of the surface of the metal pillars (21) opposite to the contact metallizations (23) of the first electronic components (31; 33; 35).

After step e), the structure may be stored for later use.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method comprising:
forming, on a surface of a substrate, at least two metal pillars intended to be respectively connected to at least two first contact metallizations of an electronic component, the metal pillars each having a surface area greater than the surface area of the corresponding first contact metallization of the electronic component;
forming, over a portion only of the surface of each metal pillar, a second contact metallization;
covering the surface of the substrate, the metal pillars, and the second contact metallizations with a first resin layer;
removing the substrate to expose a surface of the metal pillars, opposite to the second contact metallizations;
bonding and electrically connecting the electronic components, by the first contact metallizations, to the surface of the metal pillars opposite to the second contact metallizations;
thinning the first resin layer to expose the surface of the second contact metallizations opposite to the metal pillars; and
cutting the first resin layer to individualize a plurality of surface-mounted electronic components.

2. The method according to claim 1, wherein the metal pillars are formed by electrolytic growth.

3. The method according to claim 1, wherein the second contact metallizations are formed by electrolytic growth.

4. The method according to claim 1, comprising, after the bonding and electrically connecting the electronic components to the surface of the metal pillars opposite to the second contact metallizations, a covering of the electronic components and of the second contact metallizations with a second resin layer.

5. The method according to claim 1, wherein, during the cutting the first resin layer, the sides of the metal pillars and of the second contact metallizations are exposed.

6. The method according to claim 1, wherein the metal pillars are made of copper, of gold, of tin, of silver, or of an alloy of a plurality of these materials.

7. The method according to claim 1, wherein the second contact metallizations are made of copper, of gold, of tin, of silver, or of an alloy of a plurality of these materials.

8. The method according to claim 1, wherein the second contact metallizations have a height in the range of 20 μm to 100 μm.

9. The method according to claim 8, wherein the second contact metallizations have a height greater than or equal to 30 μm.

10. The method according to claim 1, wherein the metal pillars have a height in the range of 80 μm to 150 μm.

11. The method according to claim 1, wherein the cutting the first resin layer is performed so that the first resin layer remains on sides of each of the plurality of surface-mounted electronic components.

12. The method according to claim 1, wherein the cutting of the first resin layer is performed so that the second contact metallizations and the metal pillars are flush with the sides of each of the plurality of surface-mounted electronic components.

13. The method according to claim 1, wherein, during the cutting the first resin layer, a first through cutting line is formed so that the second contact metallizations and the metal pillars are flush with the sides of each of the plurality of surface-mounted electronic components and a second non-through cutting line, having a cutting width greater than the cutting width of the first cutting line, is formed to expose a portion of the surface of the metal pillars opposite to the second contact metallizations.

14. A method comprising:
forming a plurality of metal pillars on a substrate;
forming a resin layer on the substrate around the metal pillars, the resin layer having a first surface opposite the substrate;
forming a plurality of openings in the resin layer from the first surface to each of the plurality of metal pillars;
forming a contact metallization in each of the plurality of openings;
exposing the plurality of metal pillars;
forming a plurality of electronic components coupled between each two adjacent metal pillars of the plurality of metal pillars; and
removing a portion of the first resin layer to expose the contact metallizations.

15. The method according to claim 14, wherein the forming a plurality of metal pillars on substrate comprises forming a bonding layer on the substrate and forming the plurality of metal pillars directly on the bonding layer.

16. The method according to claim 14, wherein each contact metallization covers only a portion of each metal pillar.

17. The method according to claim 15, wherein exposing the plurality of metal pillars includes removing the substrate and removing the bonding layer.

18. A method comprising:
forming a plurality of metal pillars on a substrate, each of the plurality of metal pillars having a first surface opposite the substrate with a first surface area;
forming a plurality of contact metallizations on the first surface of each of the plurality of metal pillars, each contact metallization having a first surface opposite the substrate with a second surface area smaller than the first surface area;
forming a resin layer on the substrate, the plurality of metal pillars, and the plurality of contact metallizations;
exposing a second surface of the plurality of metal pillars opposite the first surface of the plurality of metal pillars;
forming a plurality of electronic components coupled between each two adjacent metal pillars of the plurality of metal pillars; and
forming an opening in the resin layer between each of the plurality of electronic components to separate a plurality of surface-mounted electronic components.

19. The method according to claim 18, wherein each metal pillar of the plurality of metal pillars includes a first portion and a second portion having a different shape from the first portion, the second portion of each metal pillar being closer to the second portion of each adjacent metal pillar than to the first portion of each adjacent metal pillar.

20. The method according to claim 19, wherein the second portion of each metal pillar is coupled to an electronic component of the plurality of electronic components.
